(19) United States
(12) Patent Application Publication
(10) Pub. No.: US 2026/0352163 A1
(43) Pub. Date: Nov. 5, 2026

(54) HIGH-FREQUENCY AMPLIFIER

(71) Applicant: Mitsubishi Electric Corporation, Tokyo (JP)

(72) Inventor: Takaaki YOSHIOKA, Tokyo (JP)

(73) Assignee: Mitsubishi Electric Corporation, Tokyo (JP)

(21) Appl. No.: 18/997,640

(22) PCT Filed: Dec. 9, 2022
(86) PCT No.: PCT/JP2022/045531

§ 371 Date: Jan. 22, 2025

(51) Int. Cl. H03F 1/32; H03F 1/56; H03F 3/20; H03F 3/60

(52) U.S. Cl. CPC H03F 1/32; H03F 1/565; H03F 3/20; H03F 3/605; H03F 2200/294; H03F 2203/21112; H03F 2203/21157

(57) ABSTRACT

A high-frequency amplifier according to the present disclosure includes a plurality of amplifiers connected in series, and a stabilization circuit, a first band-rejection filter and an output bias circuit provided in each of at least two amplifiers of the plurality of amplifiers, wherein each of the stabilization circuits includes a bandpass filter and a first resistor connected in parallel with the bandpass filter, each of the first band-rejection filters has a first resonance frequency, each of the output bias circuits includes a second band-rejection filter having a second resonance frequency, and in each of the at least two amplifiers, the first resonance frequency and the second resonance frequency are different from each other and are lower than an operation frequency of the amplifier, or the first resonance frequency and the second resonance frequency are different from each other and are higher than the operation frequency of the amplifier.

### FIELD

The present disclosure relates to a high-frequency amplifier.

### BACKGROUND

PTL 1 discloses a high-frequency multistage low-noise amplifier. The high-frequency multistage low-noise amplifier includes a high-frequency input terminal, a high-frequency output terminal, and a multistage circuit provided between the high-frequency input terminal and the high-frequency output terminal. The multistage circuit includes two or more amplifiers connected in series, and each of the amplifiers includes an input matching circuit, a transistor, and an output matching circuit. A stabilization circuit including a bandpass filter and a resistor connected in parallel, and a band-rejection filter eliminating a frequency lower than an operation frequency of the amplifier are provided in each of at least two of the amplifiers of the multistage circuit. The stabilization circuit and the band-rejection filter are provided between an output terminal of the transistor and the output matching circuit of the own amplifier, or inside the output matching circuit. The bandpass filter closer to the high-frequency input terminal has the lower resonance frequency.

### CITATION LIST

### Patent Literature

### [PTL 1] WO 2022/024189

### SUMMARY

### Technical Problem

A high-frequency low-noise amplifier is generally required to have low noise of high-frequency power amplified and output and to have stability over a range from a low frequency region to a high frequency region of an operation frequency band. More specifically, in satellite communication, ground base station communication, or the like, to secure communication quality, improvement in distortion characteristics of the amplifier, elimination of unnecessary waves, and the like are required in some cases. To this end, it is necessary to suppress a gain in a frequency band near the operation band of the amplifier but different from the operation band, namely, a gain in an eliminated band in some cases. The high-frequency amplifier disclosed in PTL 1 can reduce an insertion loss over a range from a low frequency end to a high frequency end of the operation band while suppressing the gain in the eliminated band. Accordingly, a low noise factor can be obtained over a wide band, and gain flatness in the operation band can be improved.

To reduce the gain in the eliminated band by the high-frequency amplifier disclosed in PTL 1, an attenuation amount is increased by the band-rejection filter. In a case where a necessary attenuation amount or an attenuation bandwidth is large, for example, it may be necessary to arrange a plurality of inductors and capacitors constituting the band-rejection filters.

When the band-rejection filter is arranged, a circuit loss generally occurs at the resonance frequency of the band-rejection filter, and the gain of the amplifier at the resonance frequency is attenuated. However, it is practically impossible to attenuate the gain only at a single frequency. Therefore, the circuit loss also occurs in the operation band, which affects the gain or the noise factor in the operation band of the amplifier. As a result, the circuit loss may be increased, and the noise factor at the frequency end of the operation band may be deteriorated. In addition, the gain flatness in the operation band may be deteriorated.

For example, in a case where a band-rejection filter having a center frequency of 13 GHz near an operation band is provided in the amplifier that operates in the operation band from 14 GHz to 16 GHz, the gain at the frequency of 13 GHz can be reduced. However, the attenuation characteristics of the filter sweep along an axis of the frequency. Therefore, the circuit loss also occurs in the operation band. In the above-described example in which the eliminated band is lower than the operation band, reduction of the gain and deterioration of the noise factor may occur at the frequency of 14 GHz that is a low frequency end of the operation band.

To further increase the attenuation amount or the attenuation bandwidth in the eliminated band from the state, another band-rejection filter having a center frequency of 13 GHz may be added. In addition, in place of the band-rejection filter having the center frequency of 13 GHz, for example, a band-rejection filter having a center frequency of 12.8 GHz and a band-rejection filter having a center frequency of 13.2 GHz may be added. In this case, at the frequency of 14 GHz that is a low frequency end of the operation band, the gain may be further reduced, and the noise factor may be further deteriorated.

An object of the present disclosure is to provide a high-frequency amplifier that can improve the attenuation amount or the attenuation bandwidth in the eliminated band while suppressing reduction of the gain or deterioration of the noise factor in the operation band.

### Solution to Problem

A high-frequency amplifier according to the present disclosure includes a high-frequency input terminal; a high-frequency output terminal; a plurality of amplifiers connected in series and provided between the high-frequency input terminal and the high-frequency output terminal, each of the plurality of amplifiers including a transistor; a stabilization circuit provided in each of at least two amplifiers of the plurality of amplifiers; a first band-rejection filter provided in each of the at least two amplifiers; and an output bias circuit provided in each of the at least two amplifiers, and configured to supply a bias voltage to an output terminal of the corresponding transistor, wherein each of the stabilization circuits includes a bandpass filter and a first resistor connected in parallel with the bandpass filter, and is provided between the output terminal of the corresponding transistor and the high-frequency output terminal, each of the first band-rejection filters has a first resonance frequency, and is provided between the output terminal of the corresponding transistor and the high-frequency output terminal, each of the output bias circuits includes a second band-rejection filter having a second resonance frequency, and in each of the at least two amplifiers, the first resonance frequency and the second resonance frequency are different from each other and are lower than an operation frequency of the amplifier, or the first resonance frequency and the second resonance frequency are different from each other and are higher than the operation frequency of the amplifier.

### Advantageous Effects of Invention

In the high-frequency amplifier according to the present disclosure, by the first band-rejection filter and the second band-rejection filter, it is possible to improve the attenuation amount or the attenuation bandwidth in the eliminated band while suppressing reduction of the gain or deterioration of the noise factor in the operation band.

### BRIEF DESCRIPTION OF DRAWINGS

FIG. 1 is a diagram for describing a configuration of a high-frequency amplifier according to Embodiment 1.

FIG. 2 is a diagram illustrating change of a gain of the stabilization circuit to the frequency.

FIG. 3 is a diagram illustrating change of a gain of the output bias circuit to the frequency.

FIG. 4 is a diagram illustrating a sum of the gains of the stabilization circuit and the output bias circuit included in a front-stage amplifier according to Embodiment 1.

FIG. 5 is a diagram illustrating a sum of the gains of the stabilization circuit and the output bias circuit included in a rear-stage amplifier according to Embodiment 1.

FIG. 6 is a diagram illustrating the gain of each of the first band-rejection filters according to Embodiment 1.

FIG. 7 is a diagram illustrating the gain of the high-frequency amplifier according to Embodiment 1.

FIG. 8 is a diagram illustrating the noise factor of the high-frequency amplifier according to Embodiment 1.

FIG. 9 is a diagram for describing a configuration of a high-frequency amplifier according to Embodiment 2.

FIG. 10 is a diagram illustrating a sum of the gains of the stabilization circuit and the output bias circuit included in a front-stage amplifier according to Embodiment 2.

FIG. 11 is a diagram illustrating a sum of the gains of the stabilization circuit and the output bias circuit included in a rear-stage amplifier according to Embodiment 2.

FIG. 12 is a diagram illustrating the gain of the high-frequency amplifier according to Embodiment 2.

FIG. 13 is a diagram illustrating the noise factor of the high-frequency amplifier according to Embodiment 2.

FIG. 14 is a diagram for describing a configuration of a high-frequency amplifier according to Embodiment 4.

FIG. 15 is a diagram for describing a configuration of a high-frequency amplifier according to Embodiment 5.

FIG. 16 is a diagram for describing a configuration of a high-frequency amplifier according to Embodiment 6.

### DESCRIPTION OF EMBODIMENTS

High-frequency amplifiers according to the respective embodiments will be described with reference to the drawings. Identical or corresponding constitutional elements are given the same reference numerals, and the repeated description of such constitutional elements may be omitted.

### Embodiment 1

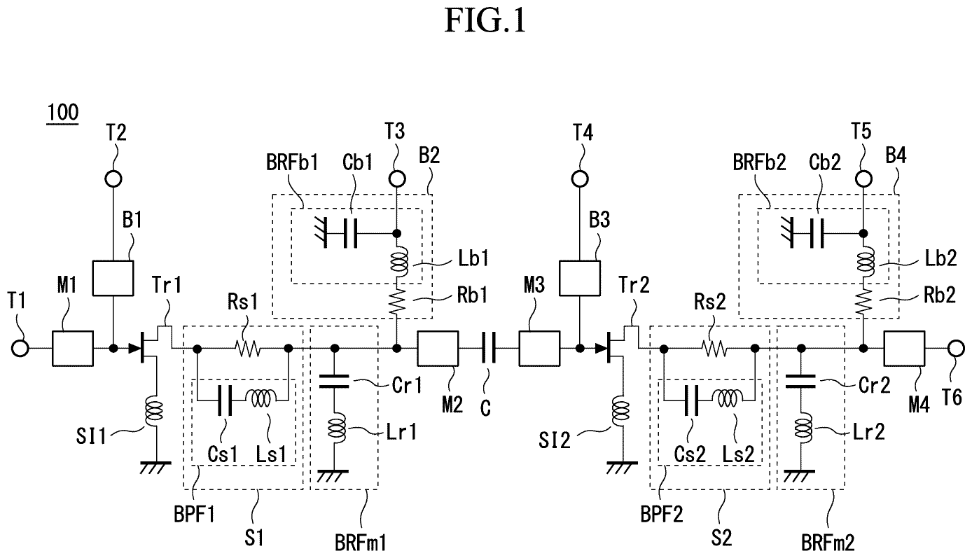

FIG. 1 is a diagram for describing a configuration of a high-frequency amplifier 100 according to Embodiment 1. The high-frequency amplifier 100 is also referred to as a high-frequency multistage low-noise amplifier. The high-frequency amplifier 100 is a high-frequency power amplifier amplifying high-frequency power of, for example, a microwave and a millimeter wave.

The high-frequency amplifier 100 includes a high-frequency input terminal T1, a high-frequency output terminal T6, and a multistage circuit provided between the high-frequency input terminal T1 and the high-frequency output terminal T6. The high-frequency input terminal T1 is a terminal for inputting high-frequency power to the high-frequency amplifier 100. The high-frequency output terminal T6 is an output terminal of the high-frequency amplifier 100, The multistage circuit includes a plurality of amplifiers connected in series. The amplifiers respectively include input matching circuits M1 and M3, transistors Tr1 and Tr2, and output matching circuits M2 and M4. In FIG. 1, two amplifiers are illustrated; however, it is sufficient for the multistage circuit to include two or more amplifiers connected in series, and the number of amplifiers is not limited.

In the example illustrated in FIG. 1, a first-stage amplifier includes the input matching circuit M1, an input bias circuit B1, an input bias power-supply terminal T2, the transistor Tr1, and a source inductor SI1. The first-stage amplifier further includes a stabilization circuit S1, a first band-rejection filter BRFm1, an output bias circuit B2, an output bias power-supply terminal T3, and the output matching circuit M2. The first-stage amplifier and a second-stage amplifier are connected through an interstage capacitor C. The second-stage amplifier includes the input matching circuit M3, an input bias circuit B3, an input bias power-supply terminal T4, the transistor Tr2, and a source inductor SI2. The second-stage amplifier further includes a stabilization circuit S2, a first band-rejection filter BRFm2, an output bias circuit B4, an output bias power-supply terminal T5, and the output matching circuit M4.

As described above, the components from the input matching circuit M1 to the output matching circuit M2 constitute the first-stage amplifier as viewed from the high-frequency input terminal T1 side. The input matching circuit M1 is an input-side matching circuit of the transistor Tr1. The input bias circuit B1 is a circuit applying a bias voltage to a gate terminal of the transistor Tr1. The input bias power-supply terminal T2 is a power-supply terminal for supplying power to the input bias circuit B1. The transistor Tr1 is an amplification dvice amplifying the high-frequency power. One end of the source inductor SI1 is connected to a source terminal of the transistor Tr1, and the other end of the source inductor SI1 is grounded.

The stabilization circuit S1 is provided between the transistor Tr1 and the output matching circuit M2. The stabilization circuit S1 includes a bandpass filter BPF1, and a resistor Rs1 connected in parallel with the bandpass filter BPF1. The bandpass filter BPF1 is, for example, a series resonance circuit that includes an inductor Ls1 and a capacitor Cs1 and resonates at a frequency fs1. It is sufficient that the stabilization circuit S1 is provided between an output terminal of the transistor Tr1 and the output matching circuit M2 belonging to the same amplifier, or inside the output matching circuit M2. In other words, it is sufficient that the stabilization circuit S1 is provided between the output terminal of the corresponding transistor Tr1 and the high-frequency output terminal T6 in the first-stage amplifier.

The first band-rejection filter BRFm1 is provided between the transistor Tr1 and the output matching circuit M2. The first band-rejection filter BRFm1 is constructed of a series resonance circuit that includes an inductor Lr1 and a capacitor Cr1 and resonates at a frequency fr. The series resonance circuit is shunt-connected. In the following, the resonance frequency fr of the first band-rejection filter BRFm1 is referred to as a first resonance frequency in some cases. It is sufficient that the first band-rejection filter BRFm1 is provided between the output terminal of the transistor Tr1 and the output matching circuit M2 belonging to the same amplifier, or inside the output matching circuit M2. In other words, it is sufficient that the first band-rejection filter BRFm1 is provided between the output terminal of the corresponding transistor Tr1 and the high-frequency output terminal T6 in the first-stage amplifier.

The stabilization circuit S1 and the first band-rejection filter BRFm1 are connected in series in this order, and are connected to the output terminal of the transistor Tr1. The stabilization circuit S1 and the first band-rejection filter BRFm1 may be connected in a reverse order.

The output bias circuit B2 is a circuit supplying a bias voltage to the output terminal of the transistor Tr1. The output bias circuit B2 is provided between the output terminal of the corresponding transistor Tr1 and the output bias power-supply terminal T3. The output bias circuit B2 includes a second band-rejection filter BRFb1, and a resistor Rb1 connected in series with the second band-rejection filter BRFb1. In the output bias circuit B2, the resistor Rb1 and an inductor Lb1 are connected in series with a bias path to the transistor Tr1. A capacitor Cb1 is shunt-connected to the bias path. The inductor Lb1 functions as a power supply path applying a bias voltage. The inductor Lb1 and the capacitor Cb1 constitute the second band-rejection filter BRFb1 resonating at a frequency fb. In the following, the resonance frequency fb of the second band-rejection filter BRFb1 is referred to as a second resonance frequency in some cases.

The output bias power-supply terminal T3 is a power-supply terminal for supplying power to the output bias circuit B2 and for supplying a bias voltage to the output terminal of the transistor Tr1. The output matching circuit M2 is an output-side matching circuit of the transistor Tr1. The interstage capacitor C is a DC cut capacitor that blocks a direct current from the output matching circuit M2 and the input matching circuit M3.

The components from the input matching circuit M3 to the output matching circuit M4 constitute the second-stage amplifier as viewed from the high-frequency input terminal T1 side. A configuration of the second-stage amplifier is similar to the configuration of the first-stage amplifier. The stabilization circuit S2 includes a bandpass filter BPF2, and a resistor Rs2 connected in parallel with the bandpass filter BPF2. The bandpass filter BPF2 is, for example, a series resonance circuit that includes an inductor Ls2 and a capacitor Cs2 and resonates at a frequency fs2.

The first band-rejection filter BRFm2 is constructed of a series resonance circuit that includes an inductor Lr2 and a capacitor Cr2 and resonates at the frequency fr. The series resonance circuit is shunt-connected. The inductor Lr2 has the same inductance as, for example, the inductor Lr1. The capacitor Cr2 has the same capacitance value as, for example, the capacitor Cr1. Therefore, the resonance frequency of the first band-rejection filter BRFm2 is equal to the resonance frequency fr of the first band-rejection filter BRFm1.

The output bias circuit B4 is a circuit supplying a bias voltage to the output terminal of the transistor Tr2. The output bias circuit B4 includes a second band-rejection filter BRFb2, and a resistor Rb2 connected in series with the second band-rejection filter BRFb2. In the output bias circuit B4, the resistor Rb2 and an inductor Lb2 are connected in series with a bias path to the transistor Tr2. A capacitor Cb2 is shunt-connected to the bias path. The inductor Lb2 and the capacitor Cb2 constitute the second band-rejection filter BRFb2 resonating at the frequency fb. The resistor Rb2 has the same resistance value as, for example, the resistor Rb1. The inductor Lb2 has the same inductance as, for example, the inductor Lb1. The capacitor Cb2 has the same capacitance value as, for example, the capacitor Cb1. Therefore, the resonance frequency of the second band-rejection filter BRFb2 is equal to the resonance frequency fb of the second band-rejection filter BRFb1.

An operation frequency of the amplifier, namely, a center value of an operation band of the amplifier is denoted by fc. Relationship of the resonance frequencies fs1 and fs2 of the respective bandpass filters BPF1 and BPF2, the first resonance frequency fr, and the second resonance frequency fb is as follows.

fb<fr≤fs1<fc<fs2

The first resonance frequency fr is lower than the operation frequency fc. The bandpass filters BPF1 and BPF2 closer to the high-frequency input terminal T1 have the lower resonance frequencies fs1 and fs2.

In the low-noise amplifier, stability in the operation band is often achieved by using a source inductor. However, loading of the source inductor may impair stability on a high-frequency side of the operation band. Therefore, it is necessary to insert a stabilization circuit having an insertion loss not only on a low-frequency side of the operation frequency but also on the high-frequency side of the operation band. In addition, it is necessary to stabilize the transistor in each stage. Therefore, the stabilization circuit S1 and the stabilization circuit S2 are preferably not connected in series continuously. Thus, the stabilization circuit S1 is preferably provided between the output terminal of the transistor Tr1 and the output matching circuit M2, or inside the output matching circuit M2. The stabilization circuit S2 is preferably provided between the output terminal of the transistor Tr2 and the output matching circuit M4, or inside the output matching circuit M4.

In addition, the first band-rejection filters BRFm1 and BRFm2 are preferably not connected in series continuously. Thus, the first band-rejection filter BRFm1 is preferably provided between the output terminal of the transistor Tr1 and the output matching circuit M2, or inside the output matching circuit M2. The first band-rejection filter BRFm2 is preferably provided between the output terminal of the transistor Tr2 and the output matching circuit M4, or inside the output matching circuit M4. This makes it possible to prevent the high-frequency power from being excessively input to all the transistors Tr1 and Tr2, and to improve distortion characteristics in each amplification stage.

As a matter of course, the output bias circuit B2 and the output bias circuit B4 are not continuously connected because the output bias circuit B2 and the output bias circuit B4 have functions of respectively applying the bias voltage to the output terminal of the transistor Tr1 and the output terminal of the transistor Tr2.

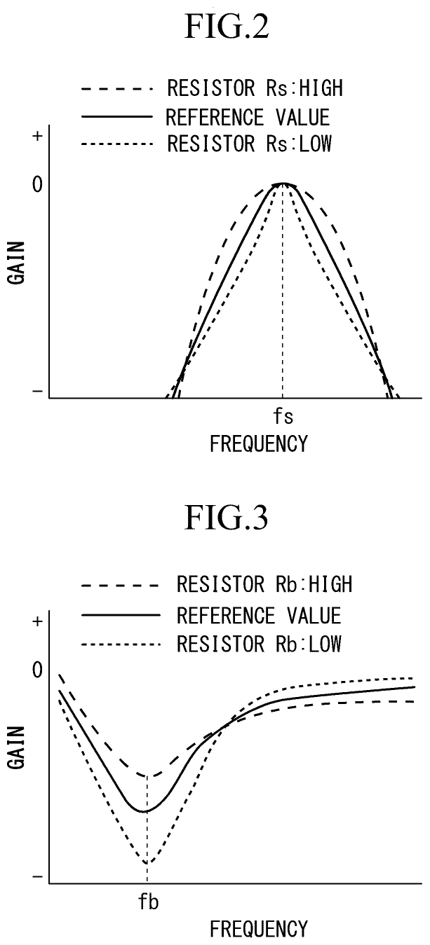

In the above-described configuration, the LC-series resonance circuit in the stabilization circuit S1 functions as the bandpass filter BPF1 that allows the power at the frequency fs1 to pass therethrough. FIG. 2 is a diagram illustrating change of a gain of the stabilization circuit to the frequency. A vertical axis in FIG. 2 indicates the gain of the stabilization circuit. A circuit loss corresponds to an absolute value of a negative value in FIG. 2. In other words, the gain is smaller and the circuit loss is larger toward a lower part in the vertical axis.

When the LC-series resonance circuit and the resistor Rs1 are connected in parallel, the resonance circuit functions as the bandpass filter at the resonance frequency fs1, and the insertion loss is ideally zero. On the other hand, when the frequency is changed from fs1, the input power is propagated through the resistor Rs1. Therefore, the circuit loss is increased, and stabilization can be achieved.

The resistance value of the resistor Rs1 is optionally set by a value of the insertion loss necessary over a range from a frequency close to the frequency fs1 to a frequency far from the frequency fs1. A dashed line in FIG. 2 indicates the gain in a case where the resistance value of the resistor Rs1 is increased from a reference value to a value enough to maintain the circuit loss necessary over the range from the frequency close to the frequency fs1 to the frequency far from the frequency fs1. At this time, a ratio of the input power propagated through the LC-series resonance circuit is increased relative to the input power propagated through the resistor Rs1. Therefore, the circuit loss of the entire stabilization circuit S1 at the frequency close to but excluding the frequency fs1 is smaller than the circuit loss at the reference value.

A dotted line in FIG. 2 indicates the gain in a case where the resistance value of the resistor Rs1 is reduced from the reference value to a value enough to maintain the circuit loss necessary at the frequency far from the frequency fs1. At this time, the ratio of the input power propagated through the resistor Rs1 is increased relative to the input power propagated through the LC-series resonance circuit. Therefore, the circuit loss of the entire stabilization circuit S1 at the frequency close to but excluding the frequency fs1 is larger than the circuit loss at the reference value.

Likewise, the LC-series resonance circuit in the stabilization circuit S2 functions as the bandpass filter BPF2 that allows the power at the resonance frequency fs2 to pass therethrough. At the frequency fs2, the resonance circuit functions as the bandpass filter, and the insertion loss is ideally zero. On the other hand, when the frequency is changed from fs2, the input power is propagated through the resistor Rs2. Therefore, the circuit loss is increased, and stabilization can be achieved.

As with the resistor Rs1, the resistance value of the resistor Rs2 is optionally set by a value of the insertion loss necessary over a range from a frequency close to the frequency fs2 to a frequency far from the frequency fs2. The resistance value of the resistor Rs2 is equal to, for example the resistance value of the resistor Rs1. The circuit loss of the entire stabilization circuit S2 is changed as illustrated in FIG. 2 based on the value of the resistor Rs2, in a manner similar to the stabilization circuit S1.

Each of the first band-rejection filter BRFm1 and BRFm2 eliminates power at the frequency fr that is input from the high-frequency input terminal T1 and is output to the high-frequency output terminal T6. The circuit loss of each of the first band-rejection filters BRFm1 and BRFm2 has frequency characteristics having a maximum value at the frequency fr and sweeping over a range from the frequency close to the frequency fr to the frequency far from the frequency fr.

Each of the second band-rejection filters BRFb1 and BRFb2 eliminates power at the frequency fb that is input from the high-frequency input terminal T1 and is output to the high-frequency output terminal T6. The circuit loss of each of the second band-rejection filters BRFb1 and BRFb2 has frequency characteristics having a maximum value at the frequency fb and sweeping over a range from the frequency close to the frequency fb to the frequency far from the frequency fr.

The output bias circuit B2 applies the bias voltage to the output terminal of the transistor Tr1, and functions as the band-rejection filter eliminating power at the frequency fb. At this time, a resistance value of the resistor Rb1 constituting the output bias circuit B2 is optionally set by a value of the insertion loss necessary over a range from a frequency close to the frequency fb to a frequency far from the frequency fb.

FIG. 3 is a diagram illustrating change of a gain of the output bias circuit B2 to the frequency. A vertical axis in FIG. 3 indicates the gain of the output bias circuit B2, and the circuit loss corresponds to an absolute value of a negative value in FIG. 3. As in FIG. 2, the gain is smaller, namely, the circuit loss is larger toward a lower part in the vertical axis.

A dashed line in FIG. 3 indicates the gain in a case where the resistance value of the resistor Rb1 is increased from a reference value to a value enough to allow increase of the circuit loss in the operation band. At this time, the frequency characteristics of the second band-rejection filter BRFb1 become gentle. Therefore, the circuit loss of the output bias circuit B2 at the frequency fb and the frequency close to the frequency fb is smaller than the circuit loss at the reference value. Further, the circuit loss of the output bias circuit B2 at the frequency far from the frequency fb is larger than the circuit loss at the reference value.

A dotted line in FIG. 3 indicates the gain in a case where the resistance value of the resistor Rb1 is reduced from the reference value to a value enough to allow reduction of the circuit loss in the eliminated band. At this time, the frequency characteristic of the second band-rejection filter BRFb1 become steep. Therefore, the circuit loss of the output bias circuit B2 at the frequency fb and the frequency close to the frequency fb is larger than the circuit loss at the reference value. Further, the circuit loss of the output bias circuit B2 at the frequency far from the frequency fb is smaller than the circuit loss at the reference value.

The frequency fb and the resistance value of the resistor Rb1 are set such that, in the case where the resistance value of the resistor Rb1 is increased from the reference value, the circuit loss of the output bias circuit B2 in the operation band of the amplifier becomes larger than the original circuit loss. Further, the frequency fb and the resistance value of the resistor Rb1 are set such that, in the case where the resistance value of the resistor Rb1 is reduced from the reference value, the circuit loss of the output bias circuit B2 in the operation band of the amplifier becomes smaller than the original circuit loss.

Likewise, the output bias circuit B4 applies the bias voltage to the output terminal of the transistor Tr2, and functions as the band-rejection filter eliminating power at the frequency fb.

A resistance value of the resistor Rb2 constituting the output bias circuit B4 is optionally set by a value of the insertion loss necessary over a range from a frequency close to the frequency fb to a frequency far from the frequency fb. The circuit loss of the output bias circuit B4 in the case where the resistance value of the resistor Rb2 is increased from the reference value and is reduced from the reference value is changed in a manner similar to the circuit loss in the output bias circuit B2.

The resistance values of the resistors Rs1, Rs2, Rb1, and Rb2 have a function of optionally setting the bias voltages applied to the output terminals of the transistors Tr1 and Tr2. Generally, under a voltage condition at which necessary reliability of the device is secured, a voltage at which performance of the transistor is maximally exerted is applied to the transistor. In the low-noise amplifier, it is necessary to apply a voltage at which the characteristics such as the noise factor and the gain become optimum, to the output terminal of the transistor.

On the other hand, a voltage is applied to each of the output bias power-supply terminals T3 and T5 from a power supply of a module or the like in which the high-frequency amplifier 100 is incorporated. The resistance values of the resistors Rs1, Rs2, Rb1, and Rb2 are set such that a desired voltage is applied to the output terminals of the transistors Tr1 and Tr2 by reducing the voltage by a necessary amount by the resistors Rs1, Rs2, Rb1, and Rb2.

Next, influence of the second band-rejection filters BRFb1 and BRFb2 on gain flatness and a noise factor in the operation band, and on attenuation characteristics of the gain in the eliminated band are described. Here, a case where the eliminated band is lower than the operation band, namely, a case where the first resonance frequency fr and the second resonance frequency fb are lower than the operation frequency of the amplifier is described. In a case where a condition of fr<fs1<fc<fs2 is satisfied, the following two cases are examined.
Case (1): Second band-rejection filter is not included in each of output bias circuits.
Case (2): Second band-rejection filter is included in each of output bias circuits.

The case (2) corresponds to the present embodiment.

In these cases, changes of the circuit loss occurring in the stabilization circuits S1 and S2, the first band-rejection filters BRFm1 and BRFm2, and the output bias circuits B2 and B4, the gain flatness and the noise factor in the operation band are described. In these cases, the operation band is 14 GHz to 16 GHz, and the center frequency of the eliminated band of each of the first band-rejection filters BRFm1 and BRFm2 is 13 GHz. The center frequency of the power eliminated by each of the second band-rejection filters BRFb1 and BRFb2 is a frequency of GHz order that is lower than 13 GHz but is not excessively low so as to have a circuit loss at the frequency of 13 GHz.

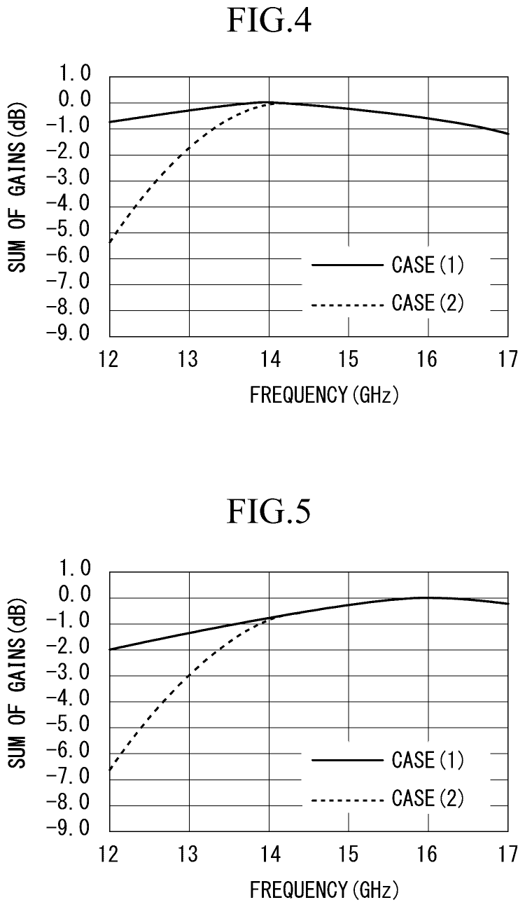

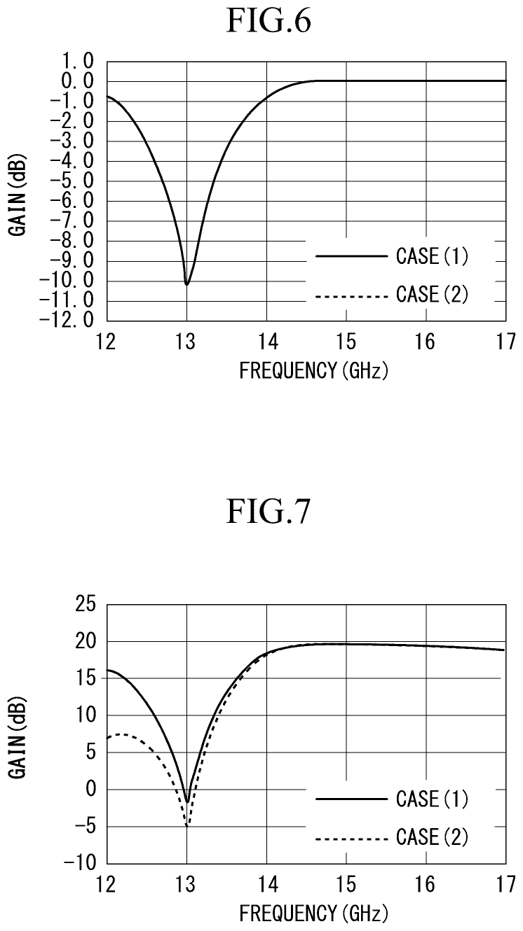

FIG. 4 is a diagram illustrating a sum of the gains of the stabilization circuit S1 and the output bias circuit B2 included in a front-stage amplifier according to Embodiment 1. FIG. 5 is a diagram illustrating a sum of the gains of the stabilization circuit S2 and the output bias circuit B4 included in a rear-stage amplifier according to Embodiment 1. FIG. 6 is a diagram illustrating the gain of each of the first band-rejection filters BRFm1 and BRFm2 according to Embodiment 1.

The circuit loss of the stabilization circuits S1 and S2, the output bias circuits B2 and B4, and the first band-rejection filters BRFm1 and BRFm2 correspond to absolute values of negative values in FIGS. 4 to 6. In calculation examples illustrated in FIGS. 4 to 6, the resonance frequency of the LC-resonance circuit constituting the stabilization circuit is set such that the circuit loss of the stabilization circuit S1 becomes zero at the frequency of 14 GHz, and the circuit loss of the stabilization circuit S2 becomes zero at the frequency of 16 GHz.

It was assumed that the attenuation amount of each of the first band-rejection filters BRFm1 and BRFm2 had the maximum value of 10 dB at the frequency of 13 GHz, and had the circuit loss of 0.6 dB at the frequency of 14 GHz, in each of the cases (1) and (2). In addition, it was assumed that the attenuation amount of each of the second band-rejection filters BRFb1 and BFFb2 had the maximum value at a frequency sufficiently smaller than 13 GHz, had the circuit loss of 1.5 dB at the frequency of 13 GHz, and had the circuit loss of substantially zero at the frequency of 14 GHz or more. Based on the above-described assumption, the gain and the noise factor of the high-frequency amplifier 100 were calculated when it was assumed that each of the transistors had the gain of 10 dB and the noise factor of 0.6 dB irrespective of the frequency, and the circuit loss caused by other than the stabilization circuits, the output bias circuits, and the band-rejection filters was absent.

FIG. 7 is a diagram illustrating the gain of the high-frequency amplifier 100 according to Embodiment 1. The gain over the range from the low frequency end of 14 GHz to the high frequency end of 16 GHz of the operation band of the amplifier is substantially equal between the cases (1) and (2). On the other hand, the attenuation amount at the frequency close to 13 GHz is larger in the case (2). Further, the attenuation bandwidth is wider in the case (2) than in the case (1). For example, the bandwidth having the gain in the eliminated band of 5 dB or less is 0.3 GHz in the case (1), and is 0.6 GHz in the case (2) corresponding to the present embodiment.

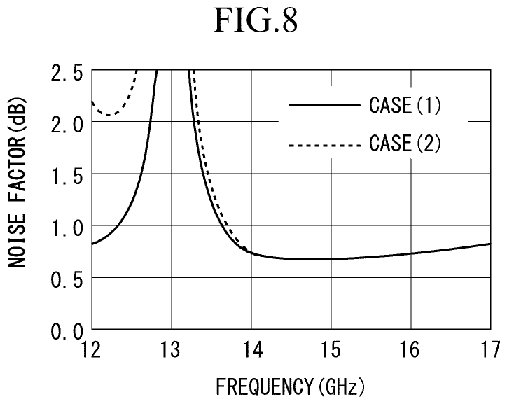

FIG. 8 is a diagram illustrating the noise factor of the high-frequency amplifier 100 according to Embodiment 1. The noise factor over the range from the low frequency end of 14 GHz to the high frequency end of 16 GHz of the operation band of the amplifier is substantially equal between the cases (1) and (2).

As described above, in the present embodiment, by combining the first band-rejection filters and the second band-rejection filters, it is possible to improve the attenuation amount and the attenuation bandwidth in the eliminated band while suppressing reduction of the gain or deterioration of the noise factor in the operation band. When the band-rejection filters are added, the gain in the operation band may be generally reduced. In contrast, in the present embodiment, it is possible to maintain the noise factor and the gain deviation equivalent to those before the band-rejection filters are added, over the range from the low frequency end to the high frequency end of the operation band.

Further, in the present embodiment, by adding the second band-rejection filters BRFb1 and BRFb2 each having a simple configuration, it is possible to improve the attenuation amount and the attenuation bandwidth in the eliminated band. This makes it possible to suppress increase in circuit scale.

In the present embodiment, the second resonance frequency fb is lower than the first resonance frequency fr. In other words, the case where the frequency eliminated by the second band-rejection filters BRFb1 and BRFb2 is lower than the frequency eliminated by the first band-rejection filters BRFm1 and BRFm2 is assumed. The present embodiment is not limited to the case, and the second resonance frequency fb may be higher than the first resonance frequency fr. In other words, it is sufficient that the first resonance frequency fr and the second resonance frequency fb are different from each other, and are lower than the operation frequency fc of the amplifier. For example, even when the first resonance frequency fr is a value lower than 13 GHz that is the center frequency of the eliminated band, and the second resonance frequency fb is 13 GHz, the effects by the present embodiment can be achieved.

These modifications can be applied, as appropriate, to high-frequency amplifiers according to the following embodiments. Note that the high-frequency amplifiers according to the following embodiments are similar to that of the first embodiment in many respects, and thus differences between the high-frequency amplifiers according to the following embodiments and that of the first embodiment will be mainly described below.

### Embodiment 2

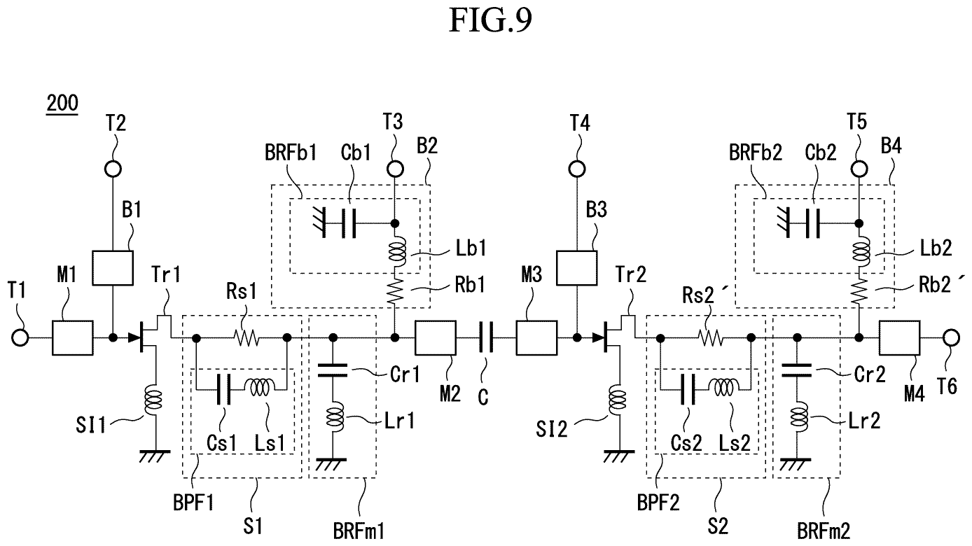

FIG. 9 is a diagram for describing a configuration of a high-frequency amplifier 200 according to Embodiment 2. In Embodiment 1, the resistor Rs1 and the resistor Rs2 have the same resistance value, and the resistor Rb1 and the resistor Rb2 have the same resistance value. The resistance values are not limited thereto, and the resistance value of the resistor Rs1 may be set larger than the resistance value of the resistor Rs2, and the resistance value of the resistor Rb1 may be set smaller than the resistance value of the resistor Rb2. In other words, in the present embodiment, the resistance values of the resistors Rs1 and Rs2 of the respective stabilization circuits S1 and S2 are larger as the corresponding amplifiers are closer to the high-frequency input terminal T1. In addition, the resistance values of the resistors Rb1 and Rb2 of the respective output bias circuits B2 and B4 are smaller as the corresponding amplifiers are closer to the high-frequency input terminal T1. The other configurations are similar to the configurations according to Embodiment 1. In FIG. 9, the resistor Rs2 having the resistance value different from the resistance value of the resistor Rs1 is denoted by a resistor Rs2′, and the resistor Rb2 having the resistance value different from the resistance value of the resistor Rb1 is denoted by a resistor Rb2′.

For description of effects by Embodiment 2, the following three cases that are varied in magnitude relationship of the resistance value of the resistor Rs1, the resistance value of the resistor Rs2, the resistance value of the resistor Rb1, and the resistance value of the resistor Rb2 are examined. The other conditions are similar to the conditions described in Embodiment 1.
Case (1): Resistance value of Rs1=resistance value of Rs2, and resistance value of Rb1=resistance value of Rb2
Case (2): Resistance value of Rs1<resistance value of Rs2, and resistance value of Rb1>resistance value of Rb2
Case (3): Resistance value of Rs1>resistance value of Rs2, and resistance value of Rb1<resistance value of Rb2

The case (1) corresponds to Embodiment 1. The case (3) corresponds to the present embodiment.

In the above-described three cases, changes of the circuit loss occurring in the stabilization circuits S1 and S2, the first band-rejection filters BRFm1 and BRFm2, and the output bias circuits B2 and B4, the gain flatness and the noise factor in the operation band are described.

As with the examination performed in Embodiment 1, the operation band is 14 GHz to 16 GHz, and the center frequency of the eliminated band of each of the first band-rejection filters BRFm1 and BRFm2 is 13 GHz. The center frequency of the power eliminated by each of the second band-rejection filters BRFb1 and BRFb2 is a frequency of GHz order that is lower than 13 GHz but is not excessively low so as to have a circuit loss at the frequency of 13 GHz.

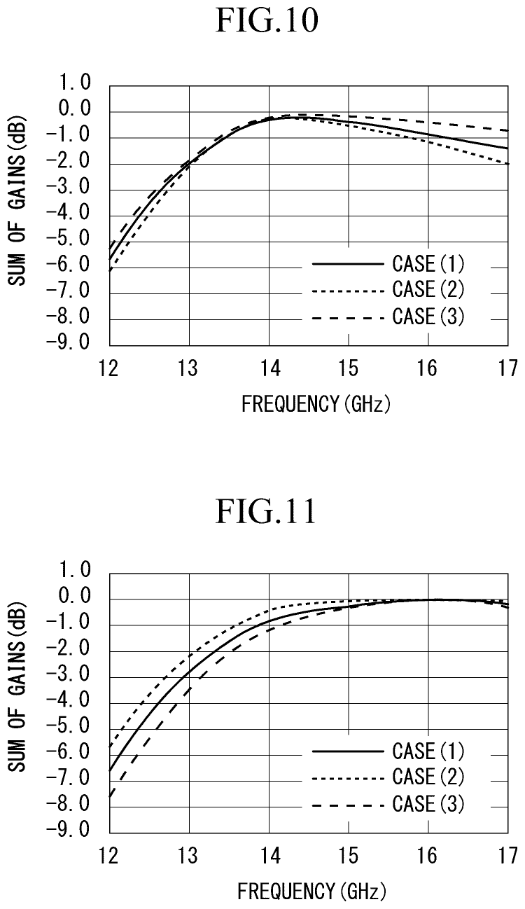

FIG. 10 is a diagram illustrating a sum of the gains of the stabilization circuit S1 and the output bias circuit B2 included in a front-stage amplifier according to Embodiment 2. FIG. 11 is a diagram illustrating a sum of the gains of the stabilization circuit S2 and the output bias circuit B4 included in a rear-stage amplifier according to Embodiment 2. As illustrated in FIGS. 10 and 11, in the calculation examples, the resonance frequency of the LC-resonance circuit constituting each of the stabilization circuits S1 and S2 is set such that the circuit loss of the stabilization circuit S1 becomes zero at the frequency of 14 GHz, and the circuit loss of the stabilization circuit S2 becomes zero at the frequency of 16 GHz in each of the cases (1) to (3).

In the case (2) as compared with the case (1), the circuit loss of the entire stabilization circuit S1 at the frequency close to but excluding the frequency fs1 is large. In addition, in the case (2) as compared with the case (1), the circuit loss of the output bias circuit B2 is large at the frequency far from the frequency fb in the operation band. Therefore, an absolute value of the sum of the gains of the stabilization circuit S1 and the output bias circuit B2 illustrated in FIG. 10, namely, the circuit loss is larger in the case (2) than in the case (1).

Likewise, in the case (2) as compared with the case (1), the circuit loss of the entire stabilization circuit S2 at the frequency close to but excluding the frequency fs2 is small. In addition, in the case (2) as compared with the case (1), the circuit loss of the output bias circuit B4 is small at the frequency far from the frequency fb in the operation band. Therefore, an absolute value of the sum of the gains of the stabilization circuit S2 and the output bias circuit B4 illustrated in FIG. 11, namely, the circuit loss is smaller in the case (2) than in the case (1).

On the other hand, in the case (3) as compared with the case (1), the circuit loss of the entire stabilization circuit S1 at the frequency close to but excluding the frequency fs1 is small. In addition, in the case (3) as compared with the case (1), the circuit loss of the output bias circuit B2 is small at the frequency far from the frequency fb in the operation band. Therefore, the absolute value of the sum of the gains of the stabilization circuit S1 and the output bias circuit B2 illustrated in FIG. 10, namely, the circuit loss is smaller in the case (3) than in the case (1).

Likewise, in the case (3) as compared with the case (1), the circuit loss of the entire stabilization circuit S2 at the frequency close to but excluding the frequency fs2 is large. In addition, in the case (3) as compared with the case (1), the circuit loss of the output bias circuit B2 is large at the frequency far from the frequency fb in the operation band. Therefore, the absolute value of the sum of the gains of the stabilization circuit S2 and the output bias circuit B4 illustrated in FIG. 11, namely, the circuit loss is larger in the case (3) than in the case (1).

Based on the above-described assumption, the gain and the noise factor of the high-frequency amplifier 200 were calculated when it was assumed that each of the transistors had the gain of 10 dB and the noise factor of 0.6 dB irrespective of the frequency, and the circuit loss caused by other than the stabilization circuits, the output bias circuits, and the band-rejection filters was absent.

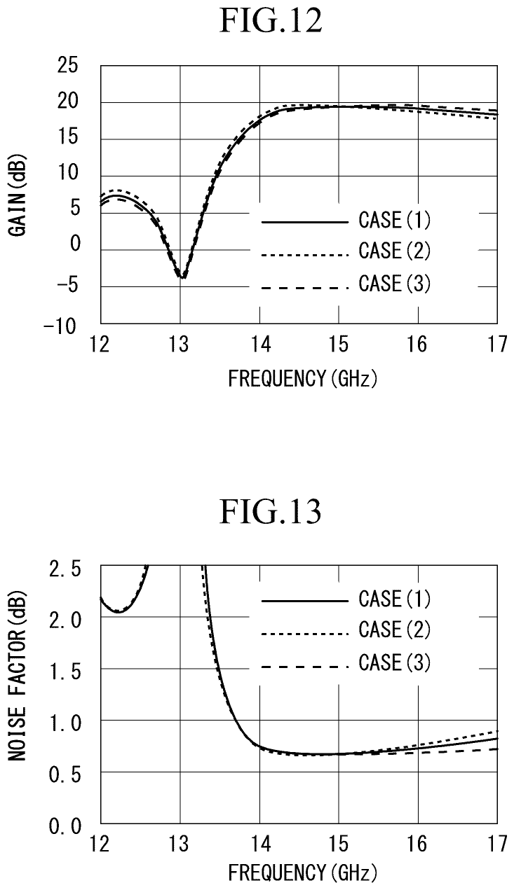

FIG. 12 is a diagram illustrating the gain of the high-frequency amplifier 200 according to Embodiment 2. It can be seen that since the attenuation characteristics of the stabilization circuit S1 and the output bias circuit B2, and the attenuation characteristics of the stabilization circuit S2 and the output bias circuit B4 are added, the eliminated band in the case (3) is wider than the eliminated band in the case (1). For example, the frequency range of the eliminated band at which the gain of the high-frequency amplifier 200 is 5 dB or less in the case (3) is wider by about 0.1 GHz than that in the case (1). As described above, in the present embodiment corresponding to the case (3), the band of the attenuation characteristics can be more widened.

FIG. 13 is a diagram illustrating the noise factor of the high-frequency amplifier 200 according to Embodiment 2. A worst value of the noise factor in the operation band is 0.73 dB in the case (1) and 0.77 dB in the case (2), whereas the worst value is 0.69 dB in the case (3).

The noise factor of a two-stage amplifier is generally calculated by the following expression.

F=F1+(F2−1)/G1 (Expression 1)

In the expression, F is the noise factor of the two-stage amplifier, F1 and F2 are noise factors of the first-stage amplifier and the second-stage amplifier, and G1 is the gain of the first-stage amplifier. According to the expression 1, even when the total circuit loss of the multistage circuit is the same, the noise factor of the first-stage amplifier is deteriorated as the circuit loss of the first-stage amplifier is larger, and therefore, the noise factor of the multistage amplifier is deteriorated. In other words, when the circuit loss of the first-stage amplifier can be reduced, even in the case where the total circuit loss by all stages is the same, the noise factor of the multistage amplifier can be improved.

The reason why the noise factor in the case (3) is smaller than the noise factor in the case (2) is because the resistance value of the resistor Rs1 is set larger than the resistance value of the resistor Rs2, and the resistance value of the resistor Rb1 is set smaller than the resistance value of the resistor Rb2. Accordingly, the circuit loss of the stabilization circuit S1 and the output bias circuit B2 can be suppressed, and the worst value of the noise factor of the first-stage amplifier in the operation band can be suppressed.

Under the technical idea, in the high-frequency amplifier 200 according to the present embodiment, the condition of the resistance value of the resistor Rs1>the resistance value of the resistor Rs2, and the condition of the resistance value of the resistor Rb1<the resistance value of the resistor Rb2 are established. As a result, it is possible to obtain smaller noise factor while maintaining the flat gain characteristics in the operation band, and it is possible to further improve the attenuation amount and the attenuation bandwidth in the eliminated band.

Note that when one of the condition of the resistance value of the resistor Rs1>the resistance value of the resistor Rs2, and the condition of the resistance value of the resistor Rb1<the resistance value of the resistor Rb2 is established, the noise factor can be improved. Thus, any one of the condition that the resistance values of the resistors Rs1 and Rs2 are larger as the corresponding amplifiers are closer to the high-frequency input terminal T1, and the condition that the resistance values of the resistors Rb1 and Rb2 are smaller as the corresponding amplifiers are closer to the high-frequency input terminal T1 may be applied to the high-frequency amplifier 200.

### Embodiment 3

The present embodiment is different from Embodiment 1 in that the eliminated band is higher than the operation band. The other configurations are similar to the configurations according to Embodiment 1. The first band-rejection filters BRFm1 and BRFm2 according to the present embodiment eliminate power at the frequency higher than the operation band of the amplifier. In other words, the first resonance frequency fr causing the maximum loss of the first band-rejection filters BRFm1 and BRFm2 is higher than the operation frequency of the amplifier. Further, the second band-rejection filters BRFb1 and BRFb2 eliminate power at a frequency higher than the frequency eliminated by the first band-rejection filters BRFm1 and BRFm2. In other words, the second resonance frequency fb causing the maximum loss of the second band-rejection filters BRFb1 and BRFb2 is higher than the first resonance frequency fr of the first band-rejection filters BRFm1 and BRFm2.

In the present embodiment, the resonance frequency fs1 of the LC-resonance circuit constituting the stabilization circuit S1 is set higher than the center frequency fc of the operation band of the amplifier. Further, the resonance frequency fs2 of the LC-resonance circuit constituting the stabilization circuit S2 is set lower than the center frequency fc of the operation band of the amplifier. As described above, the bandpass filters BPF1 and BPF2 closer to the high-frequency input terminal T1 have the higher resonance frequencies fs1 and fs2. Accordingly, the following inequality is established.

fs2<fc<fs1≤Fr<Fb

Even in the present embodiment, since the second band-rejection filters BRFb1 and BRFb2 are provided, the effects similar to the effects by Embodiment 1 can be achieved by a principle similar to the principle in Embodiment 1.

In the present embodiment, the second resonance frequency fb is higher than the first resonance frequency fr. The frequencies are not limited thereto, and the second resonance frequency fb may be lower than the first resonance frequency fr. In other words, it is sufficient that the first resonance frequency fr and the second resonance frequency fb are different from each other, and are higher than the operation frequency fc of the amplifier.

Further, the present embodiment and Embodiment 2 may be combined. In other words. one or both of the condition of the resistance value of the resistor Rs1>the resistance value of the resistor Rs2 and the condition of the resistance value of the resistor Rb1<the resistance value of the resistor Rb2 may be applied. As a result, by a principle similar to the principle in Embodiment 2, it is possible to obtain the smaller noise factor while maintaining the flat gain characteristics in the operation band, and it is possible to further improve the attenuation amount and the attenuation bandwidth in the eliminated band.

### Embodiment 4

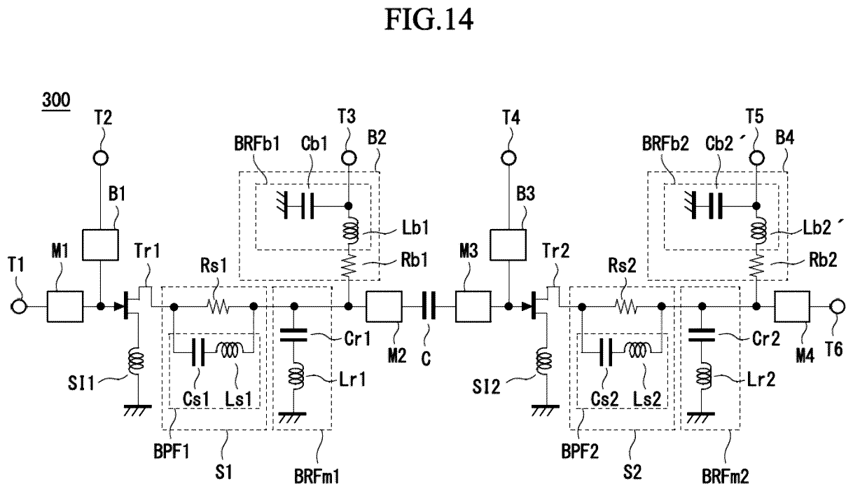

FIG. 14 is a diagram for describing a configuration of a high-frequency amplifier 300 according to Embodiment 3. In Embodiment 1, the second band-rejection filters BRFb1 and BRFb2 have the same resonance frequency, but may have resonance frequencies different from each other. In the present embodiment, the second band-rejection filter BRFb2 includes an inductor Lb2′ and a capacitor Cb2′, and therefore, the second band-rejection filter BRFb2 has a resonance frequency fb′. The second resonance frequency fb′ of the second band-rejection filter BRFb2 is set to a value that is lower than the first resonance frequency fr of the first band-rejection filters BRFm1 and BRFm2, and is higher than the second resonance frequency fb of the second band-rejection filter BRFb1. In other words, the second resonance frequencies fb and fb′ of the amplifiers are lower as the corresponding amplifiers are closer to the high-frequency input terminal T1. The other configurations are similar to the configurations according to Embodiment 1.

The resonance frequencies fs1 and fs2 of the bandpass filters BPF1 and BPF2, the center frequency fc of the operation band, the resonance frequency fr of the first band-rejection filters BRFm1 and BRFm2, and the resonance frequencies fb and fb′ of the second band-rejection filters BRFb1 and BRFb2 satisfy the following relationship.

fb<fb′<fr≤fs1<fc<fs2

Even when the total circuit loss of the multistage circuit is the same, the above-described configuration makes it possible to reduce the circuit loss of the first-stage amplifier in the operation band. Thus, as with the principle described in Embodiment 2, even in the case where the total circuit loss by all stages is the same, the noise factor of the multistage amplifier can be improved. Therefore, when the above-described conditions are applied to the high-frequency amplifier according to each of Embodiments 1 and 2, it is possible to obtain the smaller noise factor over the range from the low frequency end to the high frequency end of the operation band.

Note that the present embodiment and Embodiment 3 may be combined. In this case, the second band-rejection filter closer to the high-frequency input terminal T1 is set to have the higher second resonance frequency fb. In other words, relationship of fs2<fc<fs1≤fr<fb′<fb is satisfied. This makes it possible to obtain the smaller noise factor as compared with Embodiment 3.

### Embodiment 5

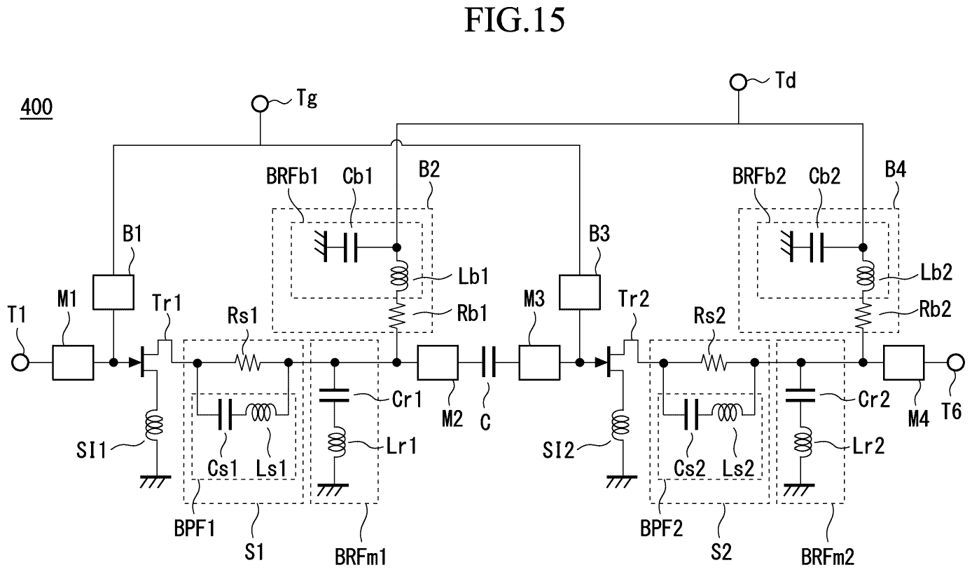

FIG. 15 is a diagram for describing a configuration of a high-frequency amplifier 400 according to Embodiment 5. In Embodiment 1, the input bias power-supply terminal T2 and the input bias power-supply terminal T4 are separately provided. In addition, the output bias power-supply terminal T3 and the output bias power-supply terminal T5 are separately provided. The configuration is not limited thereto, and the bias voltage may be supplied to the plurality of amplifiers from a common input bias common power-supply terminal Tg. Further, the bias voltage may be supplied to the plurality of amplifiers from a common output bias common power-supply terminal Td.

The present embodiment and Embodiment 2 may be combined. In other words, the condition of the resistance value of the resistor Rs1>the resistance value of the resistor Rs2, and the condition of the resistance value of the resistor Rb1<the resistance value of the resistor Rb2 may be applied. For example, a case where the transistors Tr1 and Tr2 have the same gate width, and therefore, the voltage at which the characteristics such as the noise factor and the gain become optimum is equal between the transistors Tr1 and Tr2 is considered. At this time, the resistance values are preferably set such that a sum of the resistance value of the resistor Rs1 and the resistance value of the resistor Rb1 and a sum of the resistance value of the resistor Rs2 and the resistance value of the resistor Rb2 are equal to each other.

As a result, relative to the voltage applied to the output bias common power-supply terminal Td from the power supply of the module or the like in which the high-frequency amplifier 400 is incorporated, the value of voltage drop caused by the resistor Rs1 and the resistor Rb1 and the value of voltage drop caused by the resistor Rs2 and the resistor Rb2 are equal to each other. Accordingly, both the transistors Tr1 and Tr2 can be operated at the voltage at which the characteristics such as the noise factor and the gain become optimum.

As described above, in the present embodiment, the input bias power-supply terminal and the output bias power-supply terminal are made common to the amplifiers of all stages, which makes it possible to simplify the terminal configuration and to downsize the circuit. Further, the resistance values are set as described above, which makes it possible to achieve effects similar to the effects achieved by Embodiments 1 to 4.

Note that, as described in Embodiment 2, the circuit loss of each of the amplifier has characteristics inverted from the resistance values of the two resistors included in each of the amplifiers. The two resistors are connected in series between the output bias common power-supply terminal Td and the output terminal of the transistor, By such relationship and arrangement, the above-described effects are achieved. More specifically, in the amplifier arranged at the position closest to the high-frequency input terminal T1, the resistance value of the resistor Rs1 is made large, and the resistance value of the resistor Rb1 is made small, which makes it possible to reduce the circuit loss. In the amplifier arranged at the position farthest from the high-frequency input terminal T1, it is sufficient that the resistance value of the resistor Rs2 is made small, and the resistance value of the resistor Rb2 is made large. As a result, both the transistor Tr1 and the transistor Tr2 can be operated at the voltage at which the characteristics such as the noise factor and the gain become optimum, while the sum of the resistance values is made equal among all the amplifiers.

In other words, the above-described effects cannot be achieved only by arranging the stabilization circuit in which the bandpass filter and the resistor are connected in parallel, in each stage. Likewise, the above-described effects cannot be achieved only by arranging the output bias circuit in which the band-rejection filter and the resistor are connected in series, in each stage.

### Embodiment 6

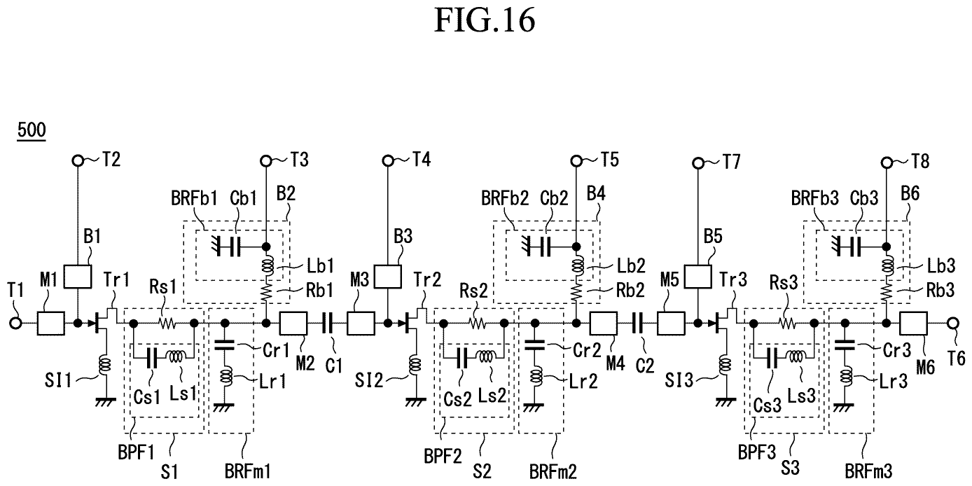

FIG. 16 is a diagram for describing a configuration of a high-frequency amplifier 500 according to Embodiment 6. The high-frequency amplifier 500 according to the present embodiment includes a three-stage amplifier. In Embodiments 1 to 5, the two-stage amplifier is mainly described; however, Embodiments 1 to 5 may be applied to a high-frequency multistage low-noise amplifier in which three or more stages of amplifiers are connected in series.

In FIG. 16, the components from the input matching circuit M1 to the output matching circuit M2 constitute the first-stage amplifier, the components from the input matching circuit M3 to the output matching circuit M4 constitute the second-stage amplifier, and components from an input matching circuit M5 to an output matching circuit M6 constitute a third-stage amplifier.

Interstage capacitors C1 and C2 are connected between the stages. The configurations of the first-stage amplifier and the second-stage amplifier are similar to the configurations according to Embodiment 1.

The third-stage amplifier includes a configuration similar to the configuration of the first-stage amplifier. The third-stage amplifier includes the input matching circuit M5, an input bias circuit B5, an input bias power-supply terminal T7, a transistor Tr3, and a source inductor SI3. The third-stage amplifier further includes a stabilization circuit S3, a first band-rejection filter BRFm3, an output bias circuit B6, an output bias power-supply terminal T8, and the output matching circuit M6.

In the stabilization circuit S3, a series resonance circuit that includes an inductor Ls3 and a capacitor Cs3 and resonates at a frequency fs3, and a resistor Rs3 are connected in parallel. In the first band-rejection filter BRFm3, a series resonance circuit including an inductor Lr3 and a capacitor Cr3 is shunt-connected. The inductor Lr3 has the same inductance as, for example, the inductor Lr1. The capacitor Cr3 has the same capacitance value as, for example, the capacitor Cr1. Therefore, a resonance frequency of the first band-rejection filter BRFm3 is equal to the resonance frequency fr of the first band-rejection filter BRFm1.

In the output bias circuit B6, a resistor Rb3 and an inductor Lb3 are connected in series with a bias path to the transistor Tr3. A capacitor Cb3 is shunt-connected to the bias path. The resistor Rb3 has the same resistance value as, for example, the resistor Rb1. The inductor Lb3 has the same inductance as, for example, the inductor Lb1. The capacitor Cb3 has the same capacitance value as, for example, the capacitor Cb1. Therefore, the resonance frequency of the second band-rejection filter BRFb3 including the inductor Lb3 and the capacitor Cb3 is equal to the resonance frequency fb of the second band-rejection filter BRFb1.

In a case where the band-rejection filter having the resonance frequency lower than the operation band of the amplifier is disposed, the resonance frequency of the series resonance circuit constituting the stabilization circuit is set to a lower frequency as the corresponding amplifier is closer to the high-frequency input terminal T1. In other words, the bandpass filter closer to the high-frequency input terminal T1 has the lower resonance frequency. This is expressed by the following inequality.

fb<fr≤fs1<fs2<fs3

On the other hand, in a case where the band-rejection filter having the resonance frequency higher than the operation band of the amplifier is disposed, the resonance frequency of the series resonance circuit constituting the stabilization circuit is set to a higher frequency as the corresponding amplifier is closer to the high-frequency input terminal T1. In other words, the bandpass filter closer to the high-frequency input terminal T1 has the higher resonance frequency. This is expressed by the following inequality.

fs3<fs2<fs1≤fr<fb

According to the present embodiment, as with Embodiments 1 to 5, the attenuation amount and the attenuation bandwidth in the eliminated band can be increased while the noise factor and the gain deviation are maintained over the range from the low frequency end to the high frequency end of the operation band.

Next, a case where the present embodiment employs the technical idea according to Embodiment 2 is described. In this case, the resistor constituting the stabilization circuit closer to the high-frequency input terminal T1 is made to have the larger resistance value, and the resistor constituting the output bias circuit closer to the high-frequency input terminal T1 is made to have the smaller resistance value. In other words, the condition of the resistance value of the resistor Rs1>the resistance value of the resistor Rs2>the resistance value of the resistor Rs3 and the condition of the resistance value of the resistor Rb1<the resistance value of the resistor Rb2<the resistance value of the resistor Rb3 are established.

A noise factor of an n-stage amplifier is calculated by an expression 2 extended from the expression 1.

F=F1+(F2−1)/G1+(F3−1)/G1G2+. . . +(Fn−1)/G1G2 . . . Gn−1 (Expression 2)

In the expression, n is a natural number, F is the noise factor of the multistage amplifier, F1, F2, F3, . . . , Fn are noise factors of first-stage to n-th-stage amplifiers, and G1, G2, . . . , Gn are gains of the first-stage to n-th-stage amplifiers.

According to the expression 2, even when the total circuit loss of the multistage circuit is the same, the noise factor of the amplifier close to the high-frequency terminal T1 is deteriorated as the circuit loss of the amplifier is larger, and therefore, the noise factor of the multistage amplifier is deteriorated. In other words, when the circuit loss of the amplifier close to the high-frequency input terminal can be reduced, even in the case where the total circuit loss by all stages is the same, the noise factor of the multistage amplifier can be improved.

As described above, in the high-frequency amplifiers in which three or more stages of the amplifiers are connected in series, the resistor of the stabilization circuit closer to the high-frequency input terminal T1 preferably has the larger resistance value, and the resistor of the output bias circuit closer to the high-frequency input terminal T1 preferably has the smaller resistance value.

In Embodiments 1 to 6, the stabilization circuit, the first band-rejection filter, and the output bias circuit including the second band-rejection filter may be provided in all of the amplifiers constituting the high-frequency amplifier, or may be provided only in specific amplifiers. It is sufficient that the features of the amplifier described in each of the embodiments are applied to at least two of the plurality of amplifiers included in the multistage circuit. In other words, in a case where the multistage circuit includes three or more amplifiers, it is sufficient that the features of the amplifier according to any of Embodiments 1 to 6 are applied to optional two or more of the amplifiers. For example, the technique according to the present embodiment may be applied to the first-stage to third-stage amplifiers of a four-stage amplifier, and an optional element among the stabilization circuit, the first band-rejection filter, and the output bias circuit may not be provided in a fourth-stage amplifier.

Note that the technical features described in the above embodiments may be combined as appropriate.

### REFERENCE SIGNS LIST

100, 200, 300, 400, 500 high-frequency amplifier, B1 input bias circuit, B2 output bias circuit, B3 input bias circuit, B4 output bias circuit, B5 input bias circuit, B6 output bias circuit, BPF1, BPF2 bandpass filter, BRFb1, BRFb2, BRFb3 second band-rejection filter, BRFm1, BRFm2, BRFm3 first band-rejection filter, C, C1, C2 interstage capacitor, Cb1, Cb2, Cb3, Cr1, Cr2, Cr3, Cs1, Cs2, Cs3 capacitor, Lb1, Lb2, Lb3, Lr1, Lr2, Lr3, Ls1, Ls2, Ls3 inductor, M1 input matching circuit, M2 output matching circuit, M3 input matching circuit, M4 output matching circuit, M5 input matching circuit, M6 output matching circuit, Rb1, Rb2, Rb3, Rs1, Rs2, Rs3 resistor, S1, S2, S3 stabilization circuit, SI1, SI2, SI3 source inductor, T1 high-frequency input terminal, T2 input bias power-supply terminal, T3 output bias power-supply terminal, T4 input bias power-supply terminal, T5 output bias power-supply terminal, T6 high-frequency output terminal, T7 input bias power-supply terminal, T8 output bias power-supply terminal, Td output bias common power-supply terminal, Tg input bias common power-supply terminal, Tr1, Tr2, Tr3 transistor

1. A high-frequency amplifier, comprising:
a high-frequency input terminal;
a high-frequency output terminal;
a plurality of amplifiers connected in series and provided between the high-frequency input terminal and the high-frequency output terminal, each of the plurality of amplifiers including a transistor;
a stabilization circuit provided in each of at least two amplifiers of the plurality of amplifiers;
a first band-rejection filter provided in each of the at least two amplifiers; and
an output bias circuit provided in each of the at least two amplifiers, and configured to supply a bias voltage to an output terminal of the corresponding transistor, wherein
each of the stabilization circuits includes a bandpass filter and a first resistor connected in parallel with the bandpass filter, and is provided between the output terminal of the corresponding transistor and the high-frequency output terminal,
each of the first band-rejection filters has a first resonance frequency, and is provided between the output terminal of the corresponding transistor and the high-frequency output terminal,
each of the output bias circuits includes a second band-rejection filter having a second resonance frequency, and
in each of the at least two amplifiers, the first resonance frequency and the second resonance frequency are different from each other and are lower than an operation frequency of the amplifier, or the first resonance frequency and the second resonance frequency are different from each other and are higher than the operation frequency of the amplifier.

2. The high-frequency amplifier according to claim 1, wherein in each of the at least two amplifiers, the first resonance frequency is lower than the operation frequency.

3. The high-frequency amplifier according to claim 2, wherein, in the at least two amplifiers, the bandpass filters closer to the high-frequency input terminal have lower resonance frequencies.

4. The high-frequency amplifier according to claim 2, wherein, in each of the at least two amplifiers, the second resonance frequency is lower than the first resonance frequency.

5. The high-frequency amplifier according to claim 2, wherein the at least two amplifiers closer to the high-frequency input terminal have the lower second resonance frequencies.

6. The high-frequency amplifier according to claim 1, wherein, in each of the at least two amplifiers, the first resonance frequency is higher than the operation frequency.

7. The high-frequency amplifier according to claim 6, wherein, in the at least two amplifiers, the bandpass filters closer to the high-frequency input terminal have higher resonance frequencies.

8. The high-frequency amplifier according to claim 6, wherein, in each of the at least two amplifiers, the second resonance frequency is higher than the first resonance frequency.

9. The high-frequency amplifier according to claim 6, wherein the at least two amplifiers closer to the high-frequency input terminal have the higher second resonance frequencies.

10. The high-frequency amplifier according to claim 1, wherein, in the at least two amplifiers, resistance values of the first resistors of the stabilization circuits are larger as the corresponding amplifiers are closer to the high-frequency input terminal.

11. The high-frequency amplifier according to claim 1, wherein
each of the output bias circuits includes a second resistor connected in series with the second band-rejection filter, and
in the at least two amplifiers, resistance values of the second resistors of the output bias circuits are smaller as the corresponding amplifiers are closer to the high-frequency input terminal.

12. The high-frequency amplifier according to claim 1, wherein
each of the output bias circuits includes a second resistor connected in series with the second band-rejection filter, and
in the at least two amplifiers, resistance values of the first resistors of the stabilization circuits are larger as the corresponding amplifiers are closer to the high-frequency input terminal, and resistance values of the second resistors of the output bias circuits are smaller as the corresponding amplifiers are closer to the high-frequency input terminal.

13. The high-frequency amplifier according to claim 12, wherein a sum of the resistance value of the first resistor and the resistance value of the second resistor is equal between the at least two amplifiers.

14. The high-frequency amplifier according to claim 13, wherein a bias voltage is supplied to the at least two amplifiers from a common output bias power-supply terminal.
